(19) United States
(12) Patent Application Publication
(10) Pub. No.: US 2014/0138782 A1
(43) Pub. Date: May 22, 2014

(54) MAGNETIC SENSING APPARATUS AND MANUFACTURING METHOD THEREOF

(71) Applicant: INDUSTRIAL TECHNOLOGY RESEARCH INSTITUTE, Hsinchu (TW)

(72) Inventor: Cheng-Wei Chien, Taoyuan County (TW)

(73) Assignee: Industrial Technology Research Institute, Hsinchu (TW)

(21) Appl. No.: 13/851,097

(22) Filed: Mar. 26, 2013

(30) Foreign Application Priority Data
Nov. 16, 2012 (TW) 101142867

(51) Int. Cl. H01L 43/02; H01L 43/12

(52) U.S. Cl. CPC H01L 43/02; H01L 43/12
USPC 257/421; 438/3

(57) ABSTRACT

A magnetic sensing apparatus and a manufacturing method thereof are provided. The magnetic sensing apparatus includes a substrate including a first surface having at least one first inclined plane, a first dielectric layer having at least one second inclined plane and at least one magnetic sensing device. The first dielectric layer is disposed on the first surface of the substrate. The surface roughness of the first dielectric layer is less than the surface roughness of the at least one first inclined plane. The inclination of the at least one second inclined plane is less than the inclination of the at least one first inclined plane. The magnetic sensing device is disposed on the at least one second inclined plane.

### CROSS-REFERENCE TO RELATED APPLICATION

This application claims the priority benefit of Taiwan application serial no. 101142867, filed on Nov. 16, 2012. The entirety of the above-mentioned patent application is hereby incorporated by reference herein and made a part of this specification.

### TECHNICAL FIELD

The disclosure relates to a magnetic sensing apparatus and a manufacturing method thereof.

### BACKGROUND

Trenches and vias play important roles in the manufacturing process of integrated circuits. In general, trenches and vias are formed by etching the substrate. After etching, the cusping produced on the top edge portion of the trenches or the vias or the undercut in the bottom portion negatively impact subsequent manufacturing processes, and especially affect the process of filling the trenches or the vias with a conducting layer the most. After filling the trenches or the vias with the conductive layer, the two defects tend to cause cavities to form in the conductive layer that may lead to open circuits. Therefore, controlling the sidewall profiles of the trenches and the vias after etching is important.

### SUMMARY

The disclosure provides a magnetic sensing apparatus having a better sensitivity.

The disclosure provides a manufacturing method for a magnetic sensing apparatus to prevent decrease in the sensitivity of the magnetic sensing apparatus.

The disclosure provides a magnetic sensing apparatus including a substrate, a first dielectric layer and at least one magnetic sensing device. The substrate includes a first surface, wherein the first surface has at least one first inclined plane. The first dielectric layer having at least one second inclined plane is disposed on the first surface of the substrate, wherein the surface roughness of the first dielectric layer is less than the surface roughness of the first inclined plane, and the inclination of the second inclined plane is less than the inclination of the first inclined plane. The magnetic sensing device is disposed on the second inclined plane.

The disclosure provides a manufacturing method for a magnetic sensing apparatus. A substrate including a first surface is provided, wherein the first surface has at least one first inclined plane. A first dielectric layer having at least one second inclined plane is formed on the substrate, wherein the surface roughness of the first dielectric layer is less than the surface roughness of the first inclined plane, and the inclination of the second inclined plane is less than the inclination of the first inclined plane. At least one magnetic sensing device is formed on the at least one second inclined plane.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of the specification. The drawings illustrate embodiments of the disclosure and, together with the description, serve to explain the principles of the disclosure.

FIG. 1A to FIG. 1B are cross-sectional schematic diagrams illustrating a manufacturing process of a magnetic sensing apparatus according to the first embodiment of the disclosure.

FIG. 2 is a cross-sectional schematic diagram illustrating a magnetic sensing apparatus according to the second embodiment of the disclosure.

FIG. 3A and FIG. 3B are cross-sectional schematic diagrams illustrating a manufacturing process of a magnetic sensing apparatus according to the third embodiment of the disclosure.

FIG. 4 is a cross-sectional schematic diagram illustrating a magnetic sensing apparatus according to the fourth embodiment of the disclosure.

FIG. 5 is a cross-sectional schematic diagram illustrating a magnetic sensing apparatus according to the fifth embodiment of the disclosure.

### DETAILED DESCRIPTION OF DISCLOSED EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

In the following, ‘first’, ‘second’, ‘third’ are only used to distinguish different devices, and are not used to determine the formation order of the devices. For instance, ‘first dielectric layer’ and ‘second dielectric layer’ separately represent two dielectric layers having different materials or formed separately, and do not mean that the first dielectric layer is formed before the second dielectric layer. In other words, the second dielectric layer may be formed before the first dielectric layer.

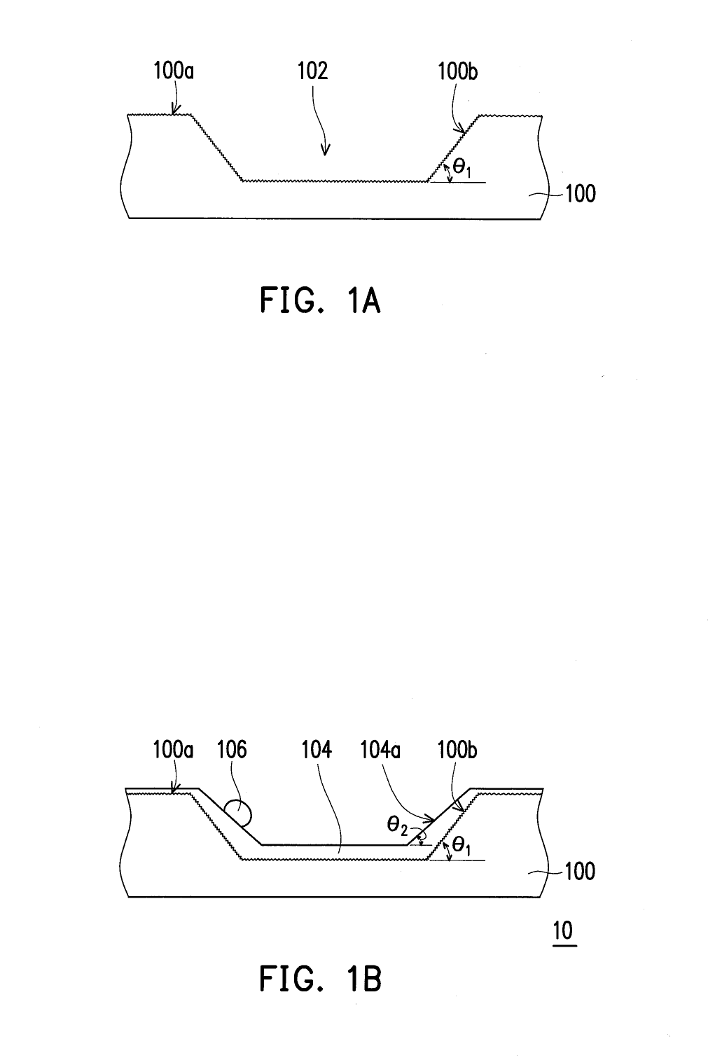

FIG. 1A to FIG. 1B are cross-sectional schematic diagrams illustrating a manufacturing process of a magnetic sensing apparatus according to the first embodiment of the disclosure. First, referring to FIG. 1A, an opening 102 is formed in a substrate 100. The substrate 100 is, for instance, a dielectric substrate or a silicon substrate. The formation method of the opening 102 is, for instance, first forming a patterned photoresist layer (not illustrated) on the substrate 100, then performing an anisotropic etching process using the patterned photoresist layer as an etch mask and removing the patterned photoresist layer. By adjusting the process parameters of the anisotropic etching process, the sidewalls of the opening 102 may have an inclined plane structure. In other words, the substrate 100 has a top surface 100a and a first inclined plane 100b joined to the top surface 100a after performing an etching process. In the embodiment, the inclination θ₁ of the first inclined plane 100b is, for instance, between 15 degrees and 80 degrees.

Both the anisotropic etching process and the removal of the patterned photoresist layer damage the substrate 100, causing the substrate 100 to have a higher surface roughness. The higher surface roughness affects subsequent manufacturing processes. For instance, when forming a film layer on the substrate 100, the film layer peels off easily from the substrate 100 due to the higher surface roughness of the substrate 100. Or, the sensitivity of a magnetic sensing apparatus is reduced significantly if the magnetic sensing device is formed on the substrate 100 having a higher surface roughness.

Since the first inclined plane 100b formed by an anisotropic etching process often has a greater inclination, when performing the lithography process on the first inclined plane 100b (the formation of the photoresist pattern on the first inclined plane 100b), the photoresist pattern often deforms after exposure due to the photolithography equipment not having enough depth of focus. The greater inclination of the first inclined plane 100b also leads to poor step-coverage of the subsequent film layer to be filled in the opening 102.

Referring to FIG. 1B, a first dielectric layer 104 is formed on the substrate 100. The formation method of the first dielectric layer 104 is, for instance, a spin coating method. The material of the first dielectric layer 104 is, for instance, hydrogen silsesquioxane (HSQ) or methyl silsesquioxane (MSQ). The thickness of the first dielectric layer 104 is, for instance, between 100 nm and 300 nm. Since the first dielectric layer 104 is formed by spin coating, the first dielectric layer 104 may have a smoother surface. That is, the surface roughness of the first dielectric layer 104 may be less than the surface roughness of the substrate 100 that has been through an etching process, so that the damaged portion of the substrate 100 may be repaired. The root mean-square-average surface roughness Rq of the first dielectric layer 104 may be between 0.2 nm and 0.3 nm. In this way, the surface roughness of the first dielectric layer 104 is less than the surface roughness of the first inclined plane 100b, improving the adhesion between the subsequent film layer formed on the first dielectric layer 104 and the first dielectric layer 104.

After the first dielectric layer 104 is formed on the substrate 100, the portion of the first dielectric layer 104 on the first inclined plane 100b forms a second inclined plane 104a. In the embodiment, since the first dielectric layer 104 is formed on the substrate 100 by a spin coating method, the inclination θ₂ of the second inclined plane 104a is less than the inclination θ₁ of the first inclined plane 100b due to the characteristics of spin coating. In the embodiment, the inclination θ₁ of the first inclined plane 100b is, for instance, between 15 degrees and 80 degrees, and the inclination θ₂ of the second inclined plane 104a may be between 10 degrees and 60 degrees. For instance, when the inclination θ₁ of the first inclined plane 100b is 30 degrees, the inclination θ₂ of the second inclined plane 104a is between 15 degrees and 25 degrees. Since the second inclined plane 104a has a smaller inclination, the problems of the photoresist deforming and poor step-coverage may be avoided.

Referring further to FIG. 1B, a magnetic sensing device 106 is formed on the second inclined plane 104a after the formation of the first dielectric layer 104 to complete a magnetic sensing apparatus 10 of the embodiment. In the embodiment, the magnetic sensing device 106 is not limited in scope, and the formation method of the magnetic sensing device is apparent to one of the ordinary skill in the art, and is not specified otherwise. The shape of the magnetic sensing device 106 may be elliptical or elongated. In the embodiment, the magnetic sensing device 106 may be formed on the second inclined plane 104a with the major axis perpendicular to the plane of the diagram. Of course, in other embodiments, the magnetic sensing device 106 may also be formed on the second inclined plane 104a with the minor axis perpendicular to the plane of the diagram. Since the first dielectric layer 104 repaired the damaged portion of the substrate 100 after forming on the substrate 100 (that is, the surface roughness of the first dielectric layer 104 is less than the surface roughness of the first inclined plane 100b), the magnetic sensing device 106 formed on the second inclined plane 104a may have better sensitivity.

Only one magnetic sensing device 106 is illustrated in the embodiment. However, in other embodiments, a plurality of the magnetic sensing devices 106 may also be formed on the second inclined plane 104a according to actual demand.

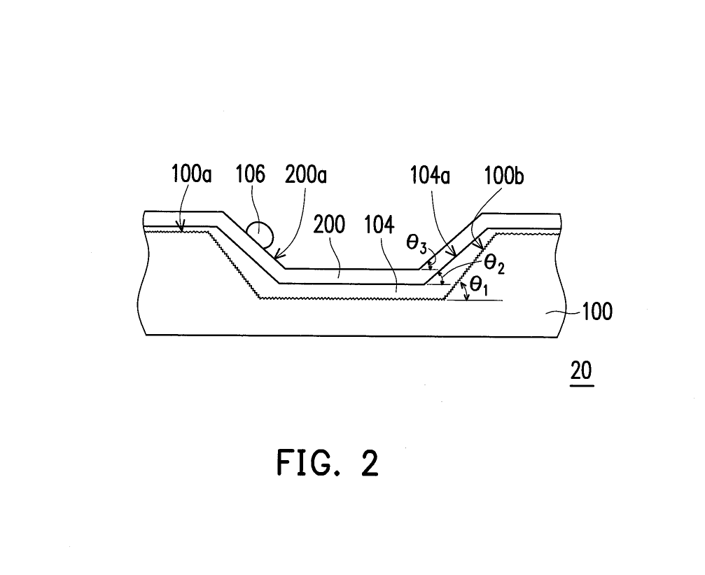

FIG. 2 is a cross-sectional schematic diagram illustrating a magnetic sensing apparatus according to the second embodiment of the disclosure. In the embodiment, the same devices from FIG. 1A and FIG. 1B have the same reference numbers. Referring to FIG. 2, in the embodiment, the difference between the magnetic sensing apparatus 20 and the magnetic sensing apparatus 10 is that a second dielectric layer 200 is disposed on the first dielectric layer 104 in the magnetic sensing apparatus 20. When manufacturing the magnetic sensing apparatus 20, the first dielectric layer 104 is first formed on the substrate 100, the second dielectric layer 200 is formed on the first dielectric layer 104. The formation method of the second dielectric layer 200 is, for instance, a chemical vapor deposition method. The material of the second dielectric layer 200 is, for instance, oxide or nitride. The second dielectric layer 200 is formed on the first dielectric layer 104, the portion of the second dielectric layer 200 on the second inclined plane 104a forms a third inclined plane 200a. The inclination θ₃ of the third inclined plane 200a formed is greater than the inclination θ₂ of the second inclined plane 104a due to the characteristics of chemical vapor deposition. The inclination θ₃ of the third inclined plane 200a is, for instance, between 15 degrees and 65 degrees. The second dielectric layer 200 may be used to adjust the angle of the inclined plane formed at the end when the inclination θ₂ of the second inclined plane 104a formed on the first inclined plane 100b by spin coating is too flat for subsequent manufacturing processes. Since the first dielectric layer 104 repaired the damaged portion of the substrate 100, the second dielectric layer 200 may have a smooth surface after the second dielectric layer 200 is formed.

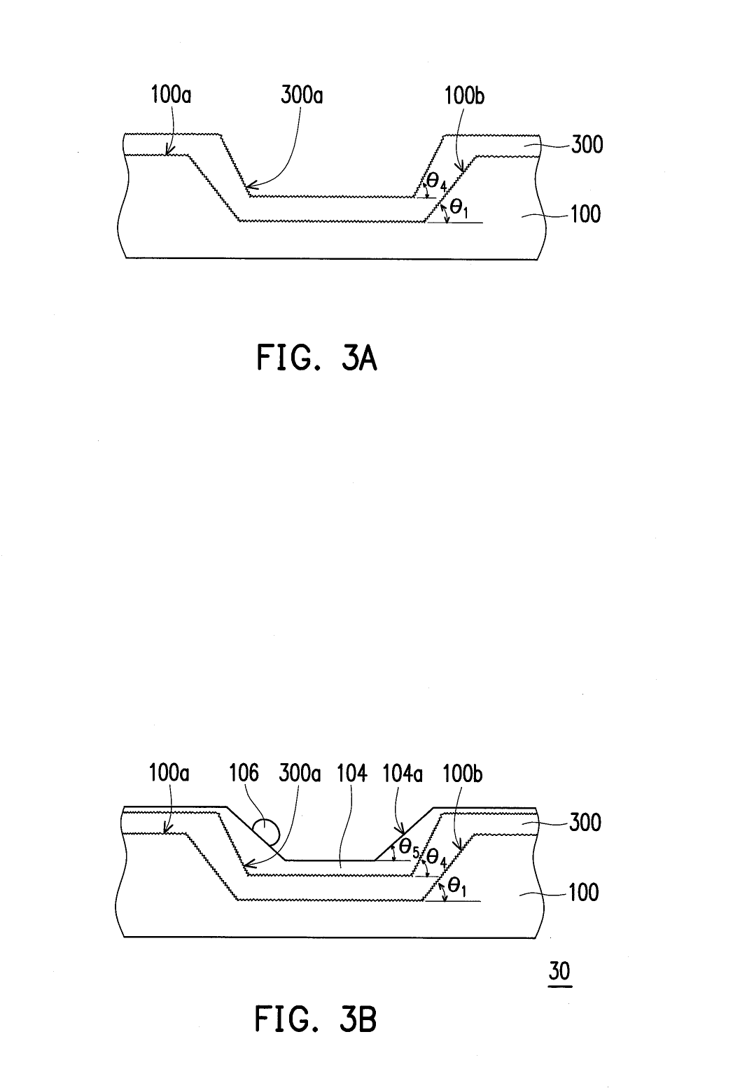

FIG. 3A and FIG. 3B are cross-sectional schematic diagrams illustrating a manufacturing process of a magnetic sensing apparatus according to the third embodiment of the disclosure. In the embodiment, the same devices from FIG. 1A and FIG. 1B have the same reference numbers Referring to FIG. 3A, an opening 102 is formed in the substrate 100. A third dielectric layer 300 is formed on the substrate 100.

The formation method of the third dielectric layer 300 is, for instance, a chemical vapor deposition method. The material of the third dielectric layer 300 is, for instance, oxide or nitride. The third dielectric layer 300 is formed on the substrate 100, the portion of the third dielectric layer 300 on the first inclined plane 100b forms a fourth inclined plane 300a. Since the third dielectric layer 300 is formed by a chemical vapor deposition method, the third dielectric layer 300 formed on the substrate 100 still has a similar roughness to the substrate 100 when the thinner thickness is deposited by chemical vapor deposition.

The inclination θ₄ of the fourth inclined plane 300a formed is greater than the inclination θ₁ of the first inclined plane 100b due to the characteristics of chemical vapor deposition. The inclination θ₄ of the fourth inclined plane 300a is between 20 degrees and 85 degrees. The third dielectric layer 300 may be used to adjust the angle of the inclined plane formed at the end when the inclination θ₁ of the first inclined plane 100b is too flat for subsequent manufacturing processes or when the inclination θ₂ of the second inclined plane 104a formed on the first inclined plane 100b by spin coating is flat for manufacturing processes.

Referring to FIG. 3B, the first dielectric layer 104 is formed on the third dielectric layer 300 The first dielectric layer 104 is formed on the third dielectric layer 300, the portion of the first dielectric layer 104 on the fourth inclined plane 300a forms a second inclined plane 104a. Since the first dielectric layer 104 is formed by spin coating, the first dielectric layer 104 may have a smoother surface. That is, the surface roughness of the first dielectric layer 104 may be less than the surface roughness of the third dielectric layer 300. The magnetic sensing device 106 is formed on the second inclined plane 104a to complete a magnetic sensing apparatus 30 of the embodiment.

In the embodiment, since the first dielectric layer 104 is formed on the third dielectric layer 300 by a spin coating method, the inclination θ₅ of the second inclined plane 104a is less than the inclination θ₄ of the fourth inclined plane 300a due to the characteristics of spin coating. The inclination θ₅ of the second inclined plane 104a is, for instance, between 15 degrees and 65 degrees. Since the second inclined plane 104a has a smaller inclination, the problems of the photoresist deforming and poor step-coverage may be avoided.

In particular, only the formations of one layer of the first dielectric layer 104 and one layer of the second dielectric layer 200/third dielectric layer 300 on the substrate 100 are described in the embodiments. However, in other embodiments, a plurality of the first dielectric layers 104 and a plurality of the second dielectric layers 200/third dielectric layers 300 may be formed on the substrate 100, and the first dielectric layers 104 and the second dielectric layers 200/third dielectric layers 300 are alternately stacked, providing that the surface roughness of the top dielectric layer is less than the surface roughness of the substrate layer 100 that has been through an etching process, and the inclination of the inclined plane of the top dielectric layer is less than the inclination of the first inclined plane 100b.

In the embodiments, the substrate 100 is a dielectric substrate. In other embodiments, the substrate may also include a silicon substrate and a dielectric substrate disposed on the silicon substrate or a thermal growth dielectric layer on the silicon substrate.

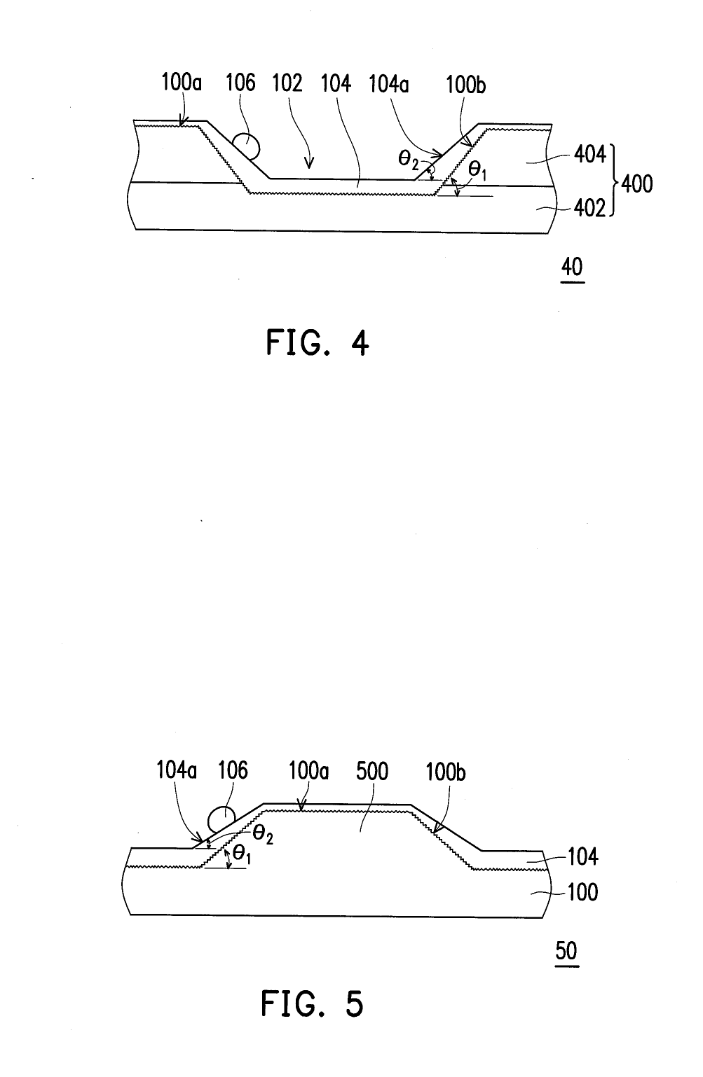

FIG. 4 is a cross-sectional schematic diagram illustrating a magnetic sensing apparatus according to the fourth embodiment of the disclosure. In the embodiment, the same devices from FIG. 1A and FIG. 1B have the same reference numbers. Referring to FIG. 4, in the embodiment, the difference between the magnetic sensing apparatus 40 and the magnetic sensing apparatus 10 is that the substrate 400 includes the silicon substrate 402 and the dielectric substrate 404 is disposed or is thermally grown on the silicon substrate 402 in the magnetic sensing apparatus 40. The opening 102 is formed in the dielectric substrate 404 and the silicon substrate 402 by an anisotropic etching process so the damaged portions of the silicon substrate 402 and the dielectric substrate 404 from the etching process have higher surface roughness. The first dielectric layer 104 disposed in the opening 102 may repair the damaged portions of the silicon substrate 402 and the dielectric substrate 404, and may prevent the problems of the photoresist pattern deforming and poor step-coverage inclination θ₁ of the first inclined plane 100b.

In other embodiments, the substrate of the magnetic sensing apparatus may include the silicon substrate and the dielectric substrate disposed on the silicon substrate.

The inclined plane is the sidewall of the opening 102 in the embodiments. The inclined plane may also be the sidewall of the platform structure in other embodiments.

FIG. 5 is a cross-sectional schematic diagram illustrating a magnetic sensing apparatus according to the fifth embodiment of the disclosure. In the embodiment, the same devices from FIG. 1A and FIG. 1B have the same reference numbers. Referring to FIG. 5, in the embodiment, the substrate 100 has a platform structure 500. The formation method of the platform structure 500 is, for instance, performing an anisotropic etching process on the substrate 100. The first inclined plane 100b of the platform structure 500 has a higher surface roughness after performing an anisotropic etching process, the first dielectric layer 104 is formed on the substrate 100 to repair the damaged portion of the substrate 100, and to retard the inclination θ₁ of the first inclined plane 100b.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. A magnetic sensing apparatus, comprising:
a substrate, comprising a first surface, wherein the first surface has at least one first inclined plane;
a first dielectric layer, having at least one second inclined plane, disposed on the first surface of the substrate, wherein the surface roughness of the first dielectric layer is less than the surface roughness of the at least one first inclined plane, and the inclination of the at least one second inclined plane is less than the inclination of the at least one first inclined plane; and
at least one magnetic sensing device, disposed on the at least one second inclined plane.

2. The magnetic sensing apparatus of claim 1, wherein the inclination of the at least one first inclined plane is between 15 degrees and 80 degrees, and the inclination of the at least one second inclined plane is between 10 degrees and 60 degrees.

3. The magnetic sensing apparatus of claim 1, further comprising a second dielectric layer, disposed on the first dielectric layer, wherein the second dielectric layer has at least one third inclined plane, and the inclination of the at least one third inclined plane is greater than the inclination of the at least one second inclined plane.

4. The magnetic sensing apparatus of claim 3, wherein the inclination of the at least one third inclined plane is between 15 degrees and 65 degrees.

5. The magnetic sensing apparatus of claim 1, further comprising a third dielectric layer, disposed between the first dielectric layer and the substrate, wherein the third dielectric layer has at least one fourth inclined plane, and the inclination of the at least one fourth inclined plane is greater than the inclination of the at least one first inclined plane.

6. The magnetic sensing apparatus of claim 5, wherein the inclination of the at least one fourth inclined plane is between 20 degrees and 85 degrees, and the inclination of the at least one second inclined plane is between 15 degrees and 65 degrees.

7. The magnetic sensing apparatus of claim 1, wherein the substrate comprises a silicon substrate and a dielectric substrate, and the dielectric substrate is disposed or thermally grown on the silicon substrate.

8. A manufacturing method for a magnetic sensing apparatus, comprising:
providing a substrate, wherein the substrate comprises a first surface, and the first surface has at least one first inclined plane;
forming a first dielectric layer having at least one second inclined plane on the substrate, wherein the surface roughness of the first dielectric layer is less than the surface roughness of the at least one first inclined plane, and the inclination of the at least one second inclined plane is less than the inclination of the at least one first inclined plane; and
forming at least one magnetic sensing device on the at least one second inclined plane.

9. The method of claim 8, wherein the formation method of the first dielectric layer comprises a spin coating method.

10. The method of claim 8, wherein the inclination of the at least one first inclined plane is between 15 degrees and 80 degrees, and the inclination of the at least one second inclined plane is between 10 degrees and 60 degrees.

11. The method of claim 8, further comprising the formation of a second dielectric layer having at least one third inclined plane on the first dielectric layer after the formation of the first dielectric layer and before the formation of the at least one magnetic sensing device, and the inclination of the at least one third inclined plane is greater than the inclination of the at least one second inclined plane.

12. The method of claim 11, wherein the inclination of the at least one third inclined plane is between 15 degrees and 65 degrees.

13. The method of claim 11, wherein the manufacturing method of the second dielectric layer comprises a chemical vapor deposition method.

14. The method of claim 8, further forming a third dielectric layer having at least one fourth inclined plane on the substrate before the formation of the first dielectric layer, and the inclination of the at least one fourth inclined plane is greater than the inclination of the at least one first inclined plane.

15. The method of claim 14, wherein the inclination of the at least one fourth inclined plane is between 20 degrees and 85 degrees, and the inclination of the at least one second inclined plane is between 15 degrees and 65 degrees.

16. The method of claim 14, wherein the formation method of the third dielectric layer comprises a chemical vapor deposition method.

17. The method of claim 8, wherein the substrate comprises a silicon substrate and a dielectric substrate, and the dielectric substrate is disposed on the silicon substrate.

18. The method of claim 8, wherein the formation method of the at least one first inclined plane comprises performing an anisotropic etching process to the substrate.
